(19) United States
(12) Patent Application Publication
(10) Pub. No.: US 2011/0206916 A1
(43) Pub. Date: Aug. 25, 2011

(54) METHOD FOR PRODUCING A MULTI-COLORED LASER-INSCRIBABLE FILM

(75) Inventors: Michael Siebert, Wedel (DE); Philipp Preuss, Neuenhaus (DE)

(73) Assignee: tesa SE, Hamburg (DE)

(21) Appl. No.: 12/994,272

(22) PCT Filed: Aug. 28, 2009
(86) PCT No.: PCT/EP2009/061124

§ 371 Date: May 11, 2011

(30) Foreign Application Priority Data
Sep. 9, 2008 (DE) 10 2008 046 461.9

(51) Int. Cl. B32B 7/02; B41M 5/24; C23C 14/28

(52) U.S. Cl. 428/215; 427/146; 427/595; 428/212

(57) ABSTRACT

The invention relates to a method for producing a multi-coloured laser-inscribable film, wherein a first lacquer layer is applied to a support and at least one other lacquer layer is applied to the first lacquer layer. The colours of two lacquer layers that are superimposed differ from each other. According to the invention, the first and the other lacquer layers are respectively formed from a printing lacquer, the printing lacquer layers are designed such that they have absorption rates which differ up to 20% and the printing lacquers are printed thereon to form the lacquer layers.

The invention relates to a method for producing a multi-colored laser-inscribable film having the features of the preamble of claim 1, and to a multi-colored laser-inscribable film according to the preamble of claim 15.

For the identification of parts on vehicles, machines, electrical and electronic devices, packaging etc. increasing use is being made of technical labels, for example as type plates, as a control label for process flows, as a packaging label or as guarantee and test badges. In order to inscribe such plates or labels, powerful controllable lasers are widely used, with the aid of which markings such as script, codings and the like can be produced. Stringent requirements are placed on the material to be inscribed. For instance, it should be possible to carry out the inscribing rapidly, the resolution capacity should be high, application should be simple and the material should have a high resistance to mechanical, physical and chemical effects. Common materials, for example printed paper, anodized or lacquered aluminum or PVC films do not fulfill all these requirements.

EP 1 440 133 B1, which forms the starting point of the present invention, discloses a production method for a laser-inscribable film which fulfills the requirements mentioned above. The laser-inscribable film is formed to be self-supporting, but it is produced on a process carrier, the so-called support carrier film. To this end, a thin layer of a UV-curable printing lacquer is printed onto the process carrier. This printing carrier layer then forms the laser-inscribable layer, also referred to as an engraving layer. A thicker layer of an electron beam-curable acrylate lacquer is spread onto this printing lacquer layer. After curing by means of an electron beam method, the acrylate lacquer layer forms the carrier of the laser-inscribable film and the process carrier can be removed. The thick acrylate lacquer layer furthermore has a different color, with the highest possible contrast, from the printing lacquer layer. After partial removal of the printing lacquer layer by laser irradiation for inscribing, the acrylate lacquer layer shows through at the positions where the printing lacquer layer has been removed, and the inscription is therefore visible. EP 1 440 133 B1 furthermore describes a multi-colored nature of the laser-inscribable film, by virtue of the fact that printing lacquer layers of different colors can be arranged next to one another and a different coloration is therefore achieved locally.

A similar product structure is also disclosed by DE 100 48 665 A1, in which a laser-inscribable layer based on an electron beam-curable (EBC) acrylate lacquer layer is provided. The acrylate lacquer contains an additive, which exhibits a colored change under laser irradiation and therefore forms an inscription. Further additives for coloration may also be contained in the acrylate lacquer layer, for example titanium dioxide for a white colored layer. Laser-inscribable films are furthermore known in which pigments, for example metal oxides or carbon black are added as laser absorbers (DE 10 2004 057 918 A1, WO 2004/045857 A2, WO 2005/033218 A1).

Multi-layered laminates, which allow multi-colored inscribing by means of laser irradiation, are furthermore known in the prior art. The individual laminate layers must be made relatively thick, in order to avoid inadvertent inscribing of the layer arranged immediately below the layer to be inscribed, or transparent buffer layers must be introduced between the colored layers. In both cases, rapid laser inscribing is not possible owing to the mass of material to be ablated, and production of the laminate is furthermore elaborate and expensive.

It is therefore an object of the present invention to provide a multi-colored laser-inscribable film, which is both easy to produce and allows rapid and process-stable laser inscribing.

The aforementioned object is achieved in a method for producing a multi-colored laser-inscribable film having the features of the preamble of claim 1 by the features of the characterizing part of claim 1. An alternative solution provides a multi-colored laser-inscribable film as claimed in claim 15. Preferred configurations and refinements are the subject-matter of the respective dependent claims.

The teaching of the invention is firstly based on the fundamental discovery that it is possible to apply not just a single printing lacquer layer onto a carrier material but also, for multi-colored laser inscribing, a plurality of printing lacquer layers above one another, in each case independently of one another. This possibility has not previously been recognized, since the application of a plurality of printing lacquer layers requires not only precise tuning of the printing method in respect of each printing lacquer layer, but also a well-defined laser absorption in each of the color layers, which should be substantially homogeneous over the entire printing lacquer layer composite.

Here and in what follows, a printing lacquer layer refers to a lacquer layer which is printed, in particular by means of a flexographic printing method.

A printing lacquer layer in this context is furthermore an engraving layer, i.e. an identifier can also be introduced into the printing lacquer layer by means of laser irradiation, for example by local removal of the engraving layer, a local change of the optical properties (for example reflection, transmission, color) or the like.

Compared with other lacquer layers, and also compared with laminate layers, the use of printing lacquer layers offers the advantage that they can be applied relatively thinly. This leads to the possibility of more rapid laser inscribing, since a thin layer can be inscribed more rapidly owing to the reduced mass ablation during the laser inscribing. In particular, printing lacquer layers are specifically applied with a mass application of from about 1 g/m² to about 3 g/m², while the mass application of EBC acrylate lacquer layers is typically at least about 10 g/m². The printing lacquer layers furthermore readily permit flexible/arbitrary coloration.

By using a plurality of differently colored printing lacquer layers, multi-colored inscriptions can then be achieved by carrying out the laser inscribing in such a way that one or more of the printing lacquer layers are locally removed by laser irradiation, so that the layer respectively lying underneath shows through. Depending on the coloration of the various printing lacquer layers, differently colored inscribing can therefore be carried out. The problem during the laser inscribing, however, is now to ensure that the material allows accurately targeted laser inscribing, i.e. although layer ablation of each individual layer takes place fully, the layer respectively lying underneath is not co-ablated.

In order to allow a maximally uniform printing process for the various printing lacquer layers, according to the invention the absorption coefficients of the respective printing lacquer layers are as uniform as possible with one another. According to the invention, the absorption rate of each printing lacquer layer for conventional wavelengths in laser inscribing differs by no more than 20%, preferably by no more than 15%, more preferably by no more than 10%, from the absorption rates of the other printing lacquer layers. This reference value for the absorption coefficient refers to the wavelength of about 1064 nm which is typical for an Nd:YAG laser. In the present case, this may be achieved in particular by corresponding adaptation of the respective proportions of titanium dioxide and/or carbon black inside the printing lacquer layer.

Both additives are distinguished as good laser absorbers. These two additives are furthermore distinguished by good compatibility with the other constituents of printing lacquers. By adding titanium dioxide and/or carbon black as laser absorbers, it is also possible to use a printing lacquer of arbitrary color. The actual coloring pigment of the printing lacquer no longer needs to fulfill any particular absorption properties in respect of the interaction with the laser radiation. In particular, a laser-inscribable printing lacquer layer may therefore be formed as a yellow printing lacquer layer. In the past, with other systems, this has not been possible or possible only with very great outlay.

In a preferred configuration, the printing lacquer layers are respectively arranged directly on one another, i.e. no further interlayers are provided.

This is particularly advantageous in particular with a view to a configuration of the film which is as thin and economical as possible.

In another preferred configuration, the individual printing lacquer layers are based on UV-curing printing lacquers. This allows particularly simple and rapid drying of the respective printing lacquer layers.

Furthermore, in a preferred embodiment each printing lacquer layer is cured before printing with the next printing lacquer layer. In this way, it is possible to ensure that mixing of the individual printing lacquer layers, and therefore mixing of the respective colors, is avoided. Depending on the configuration of the printing lacquer layer, the curing may for example be carried out by UV irradiation, electron beam curing, heat treatment or the like.

In one configuration of the production method, the carrier on which the printing lacquer layers are applied is a process carrier, which is removed again after applying and curing the printing lacquer layers. This is advantageous in particular when the film formed from the printing lacquer layers is formed so as to be self-supporting, which is to say no additional carrier is provided. As an alternative or in addition, however, an additional permanent carrier may be provided. If the layer sequence initially provided, for example for production reasons, is intended to be arranged in the reverse order in the final product, then the permanent carrier will be laminated onto the printing lacquer layers after they have been cured, and then the process carrier will be removed.

The individual printing lacquer layers may respectively be applied surface-wide or only partially, for example in the form of a logo or the like.

A proportion of at least 5%, preferably at least 10%, has been found to be particularly advantageous for the additive titanium dioxide. With respect to carbon black, proportions of at least 2%, preferably at least 4, have been found to be optimal.

The printing lacquer layer is furthermore formed as freely as possible from thickness variations. Within each printing lacquer layer, the layer thickness should not differ by more than 10% from the average layer thickness. Such a layer thickness quality can be achieved particularly well by printing the printing lacquer layers on, in particular by the flexographic printing method.

In order to achieve on the one hand a sufficient color contrast and on the other hand an inscribing efficiency which is as high as possible, the printing lacquer layer should have a layer thickness of between about 1 μm and about 10 μm, preferably between about 1 μm and about 5 μm.

The layer thickness of the carrier is preferably between about 50 μm and about 200 μm. In principle all films and film composite systems may be envisaged. In particular, for example, polymer films such as polyethylene film, PVC film or the like are suitable. With respect to the carrier, it is merely expedient to ensure good adhesion of the printing lacquer layer on it. Optionally, this may be done by applying an additional adhesion promoter, as is known from the prior art.

In a particularly preferred configuration, the laser-inscribable film is formed as an adhesive film, in particular as a self-adhesive film, by applying an adhesive layer. The adhesive layer may be based on any adhesive compounds such as are known from the prior art, in particular on so-called pressure-sensitive adhesive compounds. If the laser-inscribable film has a permanent carrier, then for the sake of simple production the adhesive layer will preferably be applied onto the opposite side of the carrier from the printing lacquer layers. As an alternative, moreover, the adhesive layer may also be applied onto the top lacquer layer. In this case, however, the carrier should likewise be formed in such a way that it is laser-inscribable, so that the inscribing can be carried out through the carrier. This arrangement has the advantage that detachment of the film after adhesive bonding or fracture of the lacquer layers, and therefore the identifier inscribed thereon, is not possible. Specifically, the printing lacquer layers themselves can be made very frangible and therefore, without the aid of a carrier, cannot be detached without damage after adhesive bonding. Since the carrier is arranged above the lacquer layers, however, the printing lacquer layers will be damaged by attempted manipulation.

The composite of printing lacquer layers as described above is preferably not only laser-inscribable but also laser-cuttable, i.e. all the layers can be cut through by laser irradiation. In order to make the production of inscribed labels as simple as possible, the carrier should also be formed so that it can be cut by means of a laser. In this way, it is possible for the purchaser of the laser-inscribable films to inscribe them individually and, at the same time, cut out a label with the desired dimensions from the film. A laser-inscribed label formed in this way has, in particular, a multi-colored individualized identifier, for example a serial number, a barcode or the like. Laser cutting of the label also makes it possible to adapt the shape in a desired way. For instance, the label may also have an individualized shape, for example with the outer configuration of an alphanumeric identifier, one or more recesses separated from one another on the label edge, or the like.

Particularly preferably, there is in this case a correlation between the individualized multi-colored identifier of the label and the individualized shape. This correlation may, for example, consist in the identifier being fully or partially reflected in the shape, or in the identifier and the individualized shape only rendering the full information together.

Further details, features, aims and advantages of the present invention will be explained in more detail below with the aid of a drawing of preferred exemplary embodiments. In the drawing:

FIG. 1 shows a schematic representation of the layer structure of a laser-inscribable film according to a first configuration,

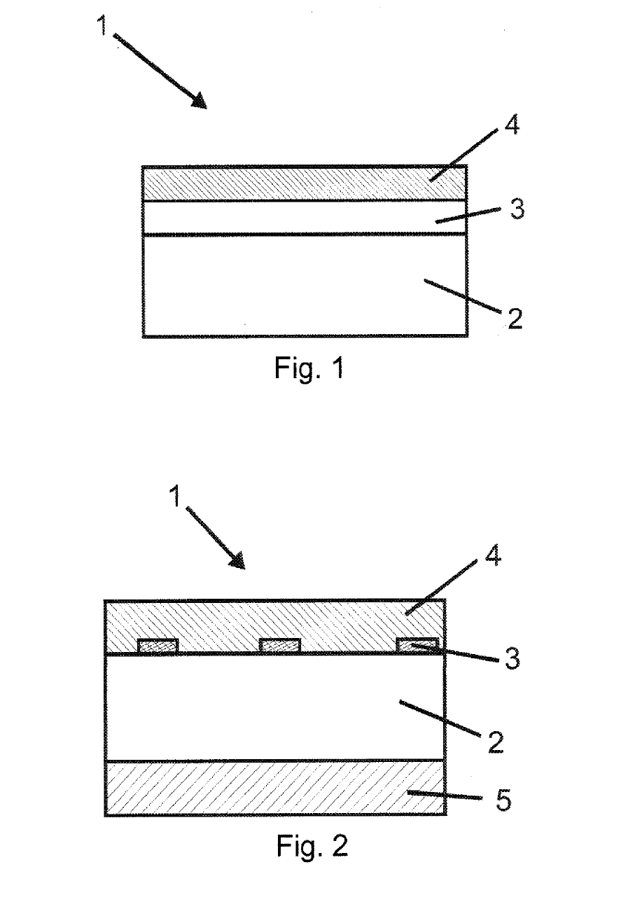

FIG. 2 shows a schematic representation of the layer structure of a laser-inscribable film according to a further configuration,

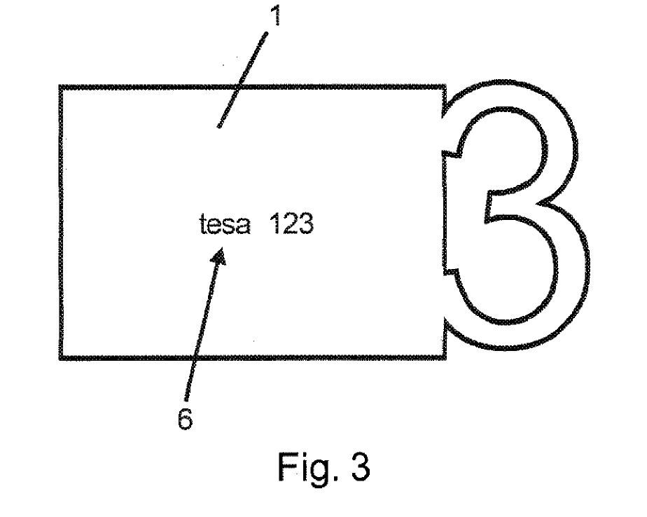

FIG. 3 shows the label of FIG. 2 in plan view.

FIG. 1 shows a laser-inscribable film 1 having a carrier 2, a first lacquer layer 3 and a further lacquer layer 4. The carrier 2 is provided as a permanent carrier of the film 1 in this case, and is formed from an approximately 100 μm thick film of polyethylene. Such an additional carrier, however, is not absolutely necessary. Depending on the configuration, the lacquer layers 3, 4 or other layers may instead fulfill this function. The two lacquer layers 3, 4 are formed surface-wide. They are respectively formed from a printing lacquer, specifically in the present case a UV-curable printing lacquer.

In order to produce the film 1, the printing lacquer for the lacquer layer 3 was first printed onto the carrier 2 by the flexographic printing method. The layer thickness was about 3 μm. The printing lacquer layer 3 was then cured by means of UV irradiation. After curing, the printing lacquer for the printing lacquer layer 4 was printed onto the cured printing lacquer layer 3 by the flexographic printing method, with a layer thickness of about 4 μm. The printing lacquer layer 4 was also cured by means of UV irradiation.

The carrier 2 is formed so as to be white, while the printing lacquer layer 3 is formed so as to be red and the printing lacquer layer 4 yellow. The coloring of the printing lacquer layers is carried out using color pigments in the printing lacquers.

Besides the color pigments known to the person skilled in the art for red and yellow, the printing lacquers of the printing lacquer layers 3, 4 furthermore comprise titanium dioxide or carbon black as laser absorbers. Owing to these constituents, the printing lacquer layers 3, 4 are particularly suitable as engraving layers, that is to say they can be inscribed locally by laser irradiation. During the inscribing, the laser radiation is locally absorbed and the other printing lacquer layer 4 is first partially removed. Subsequently or during the same inscribing run, however, the underlying printing lacquer layer 3 may also be removed by laser irradiation. The extent to which one or more printing lacquer layers 3, 4 are removed in one run or successively can be controlled by suitable selection of the laser parameters (pulse duration, intensity). In the present case, inscribing in the colors yellow, red and white is therefore possible.

The printing lacquer layer 3 has a proportion of 10% titanium dioxide and a proportion of 0.1% carbon black in the present case. The printing lacquer layer 4, on the other hand, has a proportion of 15% titanium dioxide and a proportion of 0.1% carbon black. In both cases, the addition of carbon black serves exclusively for the coloration and not the laser absorption, which is fully ensured by the sufficient addition of titanium dioxide.

By mixing the absorbers uniformly into the respective printing lacquer, the absorption coefficient is formed very homogeneously inside a printing lacquer layer. By mixing the laser absorbers individually into the printing lacquer, as a function of the intended layer thickness and the further constituents of the printing lacquer (coloring pigments, binders etc.), it is furthermore possible to arrange that the absorption rates of the individual printing lacquer layers 3, 4 do not substantially differ from one another. In the present case, the absorption rate of the printing lacquer layer 3 is about 14% less than the absorption rate of the printing lacquer layer 4. For a printing process which is as uniform as possible, the absorption rates should not differ from one another by more than 20%.

FIG. 2 shows an alternative configuration of a laser-inscribable film 1 in the form of a label. This label 1 in turn has a carrier 2, on which two lacquer layers 3, are arranged. In contrast to the previous configuration, the lacquer layer 3 is formed not surface-wide but only partially, particularly in the form of a logo. The printing lacquer layer 4, on the other hand, is formed surface-wide and thus covers the printing lacquer layer 3 as well as the carrier 2.

In this configuration as well, the two printing lacquer layers 3, 4 respectively comprise titanium dioxide and carbon black as laser absorbers, so that both printing lacquer layers 3, 4 are again formed as engraving layers. Colored inscribing is therefore once more possible by local ablation of one or both printing lacquer layers 3, 4. If the printing lacquer layer 4 is furthermore not formed so that it covers fully, the printing lacquer layer will also show through in the configuration of the logo irrespective of the laser inscribing. Likewise, for example by adding UV-fluorescent pigments, a further feature may be introduced. Since the feature is introduced below the surface, it is in particular not visible to the naked eye.

The label 1 also has an adhesive layer 5 below the carrier 2. The adhesive layer 5 in the present case is based on a pressure-sensitive adhesive compound and has a layer thickness of about 30 μm. By means of this adhesive layer 5, the label 1 can be fixed on any desired surfaces.

The label 1 is also configured in such a way that it can be cut by means of a laser, in particular by means of the same laser as is used for the laser inscribing.

FIG. 3 shows the label 1 in plan view. It can be seen therein that the outer shape of the label 1 is individualized, here specifically reproducing the contour of the last digit of a number sequence. This shaping was carried out individually together with the inscribing of a multi-colored identifier 6. The identifier 6 and the individualized shape are correlated with one another, and specifically in the present case have a matching last digit.

As an alternative, the individualized shape may also be based on other types of identifiers, for example on one or more incisions with the same width and/or a different width, in a similar way to a barcode or the like. The correlation may furthermore consist in the information being partially or fully repeated, optionally in an interleaved fashion. As an alternative, the correlation may also consist in the two information items merging to give full information only when combined.

1. A method for producing a multi-colored laser-inscribable film,
in which a first lacquer layer is applied onto a carrier and in which at least one further lacquer layer is applied onto the first lacquer layer,
wherein the colors of two lacquer layers respectively arranged above one another differ from one another, characterized in that
the first and the further lacquer layers are respectively formed from a printing lacquer,
in that the printing lacquer layers are configured so that they have absorption rates differing from one another by no more than 20% and
in that the printing lacquers are printed on in order to form the lacquer layers.

2. The method as claimed in claim 1, characterized in that
the printing lacquer layers are arranged directly on one another.

3. The method as claimed in claim 1 or 2, characterized in that
each printing lacquer layer is cured before printing with the next printing lacquer layer.

4. The method as claimed in one of the preceding claims, characterized in that
UV-curing printing lacquers are used.

5. The method as claimed in one of the preceding claims, characterized in that
a further layer, in particular a transparent protective layer or a second carrier—permanent carrier—is applied onto the top printing lacquer layer.

6. The method as claimed in claim 5, characterized in that
a process carrier, which is removed after applying the permanent carrier, is used as the first carrier.

7. The method as claimed in one of the preceding claims, characterized in that
at least one printing lacquer layer, in particular the first or last printing lacquer layer, is formed surface-wide, and the further printing lacquer layers are formed partially and/or surface-wide.

8. The method as claimed in one of the preceding claims, characterized in that
titanium dioxide and/or carbon black are respectively mixed with the printing lacquer as a laser absorber.

9. The method as claimed in one of the preceding claims, characterized in that
titanium dioxide to the extent of at least 5%, preferably at least 10%, is respectively mixed with the printing lacquer.

10. The method as claimed in one of the preceding claims, characterized in that
each printing lacquer layer is configured so that its layer thickness varies by no more than 10% of its average layer thickness, in particular by no more than 5% of its average layer thickness.

11. The method as claimed in one of the preceding claims, characterized in that
carbon black to the extent of at least 2%, preferably at least 4%, is respectively mixed with the printing lacquer.

12. The method as claimed in one of the preceding claims, characterized in that
the printing lacquer layers are printed with a thickness of between about 1 μm and about 10 μm, preferably between about 1 μm and about 5 μm.

13. The method as claimed in one of the preceding claims, characterized in that
the carrier and/or the permanent carrier is formed with a layer thickness of between about 50 μm and about 200 μm.

14. The method as claimed in one of the preceding claims, characterized in that
an adhesive layer is applied, in particular on the opposite side of the carrier from the printing lacquer layers.

15. A multi-colored laser-inscribable film, in particular produced according to one of the preceding claims,
having a carrier, a first lacquer layer and at least one further lacquer layer above the first lacquer layer,
wherein the colors of two lacquer layers respectively arranged above one another differ from one another, characterized in that
the first and the further lacquer layers are respectively formed from a printing lacquer,
in that the printing lacquer layers are configured so that they have absorption rates differing from one another by no more than 20% and
in that the printing lacquers are printed on in order to form the lacquer layers.

16. The multi-colored laser-inscribable film as claimed in claim 15, characterized in that
the printing lacquer layers are arranged directly on one another.

17. The multi-colored laser-inscribable film as claimed in claim 15 or 16, characterized in that
the printing lacquer layers are formed from UV-curing printing lacquers.

18. The multi-colored laser-inscribable film as claimed in one of claims 15 to 17, characterized in that
at least one printing lacquer layer, in particular the first or last printing lacquer layer, is formed surface-wide, and the further printing lacquer layers are formed partially and/or surface-wide.

19. The multi-colored laser-inscribable film as claimed in one of claims 15 to 18, characterized in that
the printing lacquer layers comprise titanium dioxide and/or carbon black as a laser absorber.

20. The multi-colored laser-inscribable film as claimed in one of claims 15 to 19, characterized in that
each printing lacquer layer contains a proportion of at least 5%, preferably at least 10%, of titanium dioxide.

21. The multi-colored laser-inscribable film as claimed in one of claims 15 to 20, characterized in that
each printing lacquer layer contains a proportion of at least 2%, preferably at least 4%, of carbon black.

22. The multi-colored laser-inscribable film as claimed in one of claims 15 to 21, characterized in that
the printing lacquer layers have a thickness of between about 1 μm and about 10 μm, preferably between about 1 μm and about 5 μm.

23. The multi-colored laser-inscribable film as claimed in one of claims 15 to 22, characterized in that
the carrier and/or the permanent carrier have a layer thickness of between about 50 μm and about 200 μm.

24. The multi-colored laser-inscribable film as claimed in one of claims 15 to 23, characterized in that
an adhesive layer is provided, in particular on the opposite side of the carrier from the printing lacquer layers.

25. The multi-colored laser-inscribable film as claimed in one of claims 15 to 24, characterized in that
the film is configured to be laser-cuttable.

26. A laser-inscribed label, in particular made of a laser-inscribable film as claimed in one of claims 15 to 25, characterized in that
the label is laser-cut and has an individualized multi-colored identifier.

27. The laser-inscribed label as claimed in claim 26, characterized in that
the label has an individualized shape.

28. The laser-inscribed label as claimed in claim 27, characterized in that
the individualized shape and the individualized identifier are correlated with one another.
